(19) United States
(12) Patent Application Publication
(10) Pub. No.: US 2024/0361222 A1
(43) Pub. Date: Oct. 31, 2024

(54) DROPLET DETECTION METROLOGY UTILIZING METROLOGY BEAM SCATTERING

(71) Applicant: ASML Netherlands B.V., Veldhoven (NL)

(72) Inventors: Dustin Michael Urone, San Diego, CA (US); Theodorus Wilhelmus Driessen, Asten-Heusden (NL); Daniel Jason Riggs, Poway, CA (US); Rodney D. Simmons, San Diego, CA (US); Jaden Robert Bankhead, San Diego, CA (US); Paul Alexander McKenzie, San Diego, CA (US)

(21) Appl. No.: 18/576,266

(22) PCT Filed: Jun. 24, 2022
(86) PCT No.: PCT/EP2022/067326

§ 371 Date: Jan. 3, 2024

Related U.S. Application Data
(60) Provisional application No. 63/353,068, filed on Jun. 17, 2022.
(60) Provisional application No. 63/221,632, filed on Jul. 14, 2021.

(51) Int. Cl. G01N 15/0205; H05G 2/00

(52) U.S. Cl. CPC G01N 15/0211; H05G 2/008

(57) ABSTRACT

Disclosed is an apparatus for and method of detecting a droplet of target material in a system for generating EUV radiation in which an illumination system is used to illuminate the droplet of a target material and a detector is arranged to detect radiation from the illumination system that has been forward or side scattered by the droplet of target material.

### CROSS REFERENCE TO RELATED APPLICATIONS

This application claims priority to U.S. Application No. 63/221,632, filed Jul. 14, 2021, titled DROPLET DETECTION METROLOGY UTILIZING PARTIALLY OBSCURED FORWARD SCATTER; and U.S. Application No. 63/353,068, filed Jun. 17, 2022, titled DROPLET DETECTION METROLOGY UTILIZING METROLOGY BEAM SCATTERING, both of which are incorporated herein in their entireties by reference.

### FIELD

The present disclosure relates to light sources which produce extreme ultraviolet light by excitation of a target material, in particular to the position measurement of a target material in such sources.

### BACKGROUND

Extreme ultraviolet (“EUV”) light, for example, electromagnetic radiation having wavelengths of around 50 nm or less (also sometimes referred to as soft x-rays) and including light at a wavelength of about 13 nm, is used in photolithography processes to produce extremely small features in substrates, for example, silicon wafers.

Methods for generating EUV light include, but are not limited to, altering the physical state of the target material into a plasma state. The target material includes an element, for example, xenon, lithium, or tin, with an emission line in the EUV range. In one such method, often termed laser produced plasma (“LPP”), the required plasma is produced by irradiating a target material, for example, in the form of a droplet, stream, or cluster of target material, with an amplified light beam that can be referred to as a drive laser. The plasma is typically produced in a sealed vessel, for example, a vacuum chamber, and monitored using various types of metrology equipment.

CO₂ amplifiers and lasers, which output an amplified light beam at a wavelength of about 10600 nm, can deliver certain advantages as a drive laser for irradiating the target material in an LPP process. This may be especially true for certain target materials, for example, for materials containing tin. One advantage with respect to tin is the ability to produce a relatively high conversion efficiency between the drive laser input power and the output EUV power.

In the EUV light source, EUV light may be produced in a two-step process in which a droplet of target material travelling to an irradiation site is first struck by a pre-pulse that conditions the droplet for subsequent phase conversion at the irradiation site. Conditioning in this context may include altering the shape of the droplet, e.g., flattening the droplet, or the distribution of the droplet, e.g., at least partially dispersing some of the droplet as a mist. For example, a conditioning pulse hits the droplet to modify the distribution of the target material and a main pulse hits the target to transform it to an EUV light-emitting plasma. In some systems the conditioning pulse and the main pulse are provided by the same laser and in other systems the conditioning pulse and the main pulse are provided by two separate lasers. In some systems there may be more than one additional conditioning pulse ahead of the main pulse.

It is important to “aim” the flying droplet to within a few micrometers for efficient and debris-minimized operation of the light source. In some systems the reflected light from the conditioning pulse or the main pulse, either of which is an operational pulse as opposed to a pulse intended only to measure, i.e., a metrology pulse, is analyzed. For example, U.S. Pat. No. 7,372,056, issued May 13, 2008, and titled “LPP EUV Plasma Source Material Target Delivery System,” discloses the use of a droplet detection radiation source and a droplet radiation detector that detects droplet detection radiation reflected from a droplet of target material.

All patent applications, patents, and printed publications cited herein are incorporated herein by reference in their entireties, except for any definitions, subject matter disclaimers or disavowals, and except to the extent that the incorporated material is inconsistent with the express disclosure herein, in which case the language in this disclosure controls.

U.S. Pat. No. 8,158,960, issued Apr. 17, 2012, and titled “Laser Produced Plasma EUV Light Source,” discloses the use of a droplet position detection system which may include one or more droplet imagers that provide an output indicative of the position of one or more droplets, e.g., relative to the irradiation region. The imager(s) may provide this output to a droplet position detection feedback system, which can compute a droplet position and trajectory, from which a droplet position error can be computed. The droplet position error may then be provided as an input to a controller, which can, for example, provide a position, direction and/or timing correction signal to the system to control a source timing circuit and/or to control a beam position and shaping system, e.g., to change the location and/or focal power of the light pulses being delivered to the irradiation region.

U.S. Pat. No. 8,653,491, issued Feb. 18, 2014, and titled “System, Method and Apparatus for Aligning and Synchronizing Target Material for Optimum Extreme Ultraviolet Light Output,” discloses irradiating a first one of multiple portions of a target material with a drive laser and detecting light reflected from the first portion of the target material to determine a location of the first portion of the target material.

U.S. Pat. No. 9,241,395, issued Jan. 19, 2016, and titled “System and Method for Controlling Droplet Timing in an LPP EUV Light Source,” discloses a droplet illumination module that generates two laser curtains for detecting the droplets. A droplet detection module detects each droplet as it passes through the second curtain, determines when the source laser should generate a pulse so that the pulse arrives at the irradiation site at the same time as the droplet, and sends a signal to the source laser to fire at the correct time.

U.S. Pat. No. 9,497,840, issued Nov. 15, 2016, and titled “System and Method for Creating and Utilizing Dual Laser Curtains from a Single Laser in an LPP EUV Light Source,” discloses the use of two laser curtains and sensors that detect the position of the droplets of target material as they pass through the curtains.

One droplet detection metrology technique used on an EUV source utilizes darkfield illumination in which the backscatter from a droplet passing through a laser curtain is collected near the primary focus of the collector. A metrology module detects the droplet crossing at a specific location in space to provide a trigger to the system controls to in turn provide timing for ensuing sequences to generate EUV. The layout and measurement location for such systems have several disadvantages limiting their droplet detection capability. Due to the layout of the vessel, the illuminating light source and the detector detecting backscatter from the droplet are positioned at a substantial distance away from the measurement plane. The magnitude of the distance from the measurement plane reduces the numerical aperture of the collection optics in a droplet detection module, as well as limits how tightly the droplet illumination module can be focused. This results in the need for a relatively high-power illumination laser. In addition, for droplet diameters approaching the wavelength of the illumination (about 1-2 μm diameter), there is significantly more light scattered in the forward direction than in the backwards direction.

There is therefore a need for a droplet position detection system which avoids these limitations.

### SUMMARY

The following presents a summary of one or more embodiments in order to provide a basic understanding of the embodiments. This summary is not an extensive overview of all contemplated embodiments and is not intended to identify key or critical elements of all embodiments nor set limits on the scope of any or all embodiments. Its sole purpose is to present some concepts of one or more embodiments as a prelude to the more detailed description that is presented later.

According to one aspect of an embodiment there is disclosed a metrology system in which light which has been forward scattered by the droplet is detected and used as a basis for a droplet measurement, e.g., the position, size, velocity, and/or trajectory of the droplet. An occlusion in the path of the beam of light from an illumination source prevents the beam from directly reaching the detector. Stray light, that is, light not scattered by the droplet, may also be captured to be used in combination with the forward scattered light to refine the position measurement by, for example, providing information to be used in a homodyne comparison. The use of forward scattered light makes more signal available. This makes it possible to detect droplets smaller than fully coalesced droplets such as satellites and subcoalesced droplets thus facilitating improved in-line tuning of the droplet generator.

According to an aspect of an embodiment there is disclosed an apparatus for detecting a droplet of target material for generating extreme ultraviolet radiation in an irradiation region, the apparatus comprising an illumination system arranged to illuminate with a beam of radiation a position in a trajectory of the droplet between a droplet generator and the irradiation region, a detection system arranged to receive radiation forward scattered by the droplet when the droplet traverses the position, and an occlusion arranged in an optical path between the position and the detection system to block the beam of radiation from directly reaching the detection system.

The illumination system may comprise a laser. The apparatus may further comprise a beam dump and the occlusion may be reflective and reflect the beam to the beam dump. The beam dump may comprise a sensor arranged to measure a characteristic of stray light from the beam not forward scattered by the droplet and be adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.

The detection system may measure a stray light characteristic of stray light from the beam not forward scattered by the droplet and measure a forward scattered light characteristic of light forward scattered by the droplet and the apparatus may further comprise an electronics system arranged to receive information from the detection system, the electronics system being configured to generate an indication of the presence of the droplet at the position based on a homodyne method using the stray light characteristic and the forward scattered light characteristic. The illumination system, the detection system, and the occlusion may be collinear along a common optical axis. The apparatus may further comprise an aperture positioned on the optical axis in front of the detection system to block at least some unscattered light originating from the illumination system from reaching the detection system. The apparatus may further comprise a condensing lens arranged on the optical axis between the occlusion and the aperture to focus the forward scattered light at the aperture. The apparatus may further comprise an optical filter arranged on the optical axis between the occlusion and detection system. The optical filter may comprise a bandpass filter.

The optical filter may comprise a polarization filter.

The illumination system, the detection system, and the occlusion may not be collinear. The optical axis of the illumination system may form an angle of not less than 0° and not greater than 90° with an optical axis of the detection system. The optical axis of the illumination system may form an angle of not less than 25° and not greater than 90° with an optical axis of the detection system.

The droplet may be a coalesced droplet, a subcoalesced droplet, or a microdroplet. The droplet may be a satellite droplet.

According to another aspect of an embodiment there is disclosed an apparatus for detecting a droplet in a stream of droplets of target material for generating extreme ultraviolet radiation in an irradiation region, the droplet being generated by a droplet generator comprising a tube-like element at least partially circumferentially surrounding a portion of the stream, the apparatus comprising an illumination system arranged at a first aperture in the tube-like element to illuminate with a beam of radiation a position in a trajectory of the droplet between a nozzle of the droplet generator and the irradiation region, a detection system arranged at a second aperture in the tube-like element to receive radiation forward scattered by the droplet when the droplet traverses the position, and an occlusion arranged in an optical path between the illumination system and the detection system to block the beam of radiation from directly reaching the detection system.

The illumination system may comprise a laser. The apparatus may further comprise a removable pellicle positioned at the second aperture and wherein the occlusion is reflective and arranged on the removable pellicle. The apparatus may further comprise a beam dump and wherein the occlusion is reflective and reflects at least a portion of the beam of radiation to the beam dump. The beam dump may comprise a sensor arranged to measure a characteristic of stray light from the beam not forward scattered by the droplet and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.

The detection system may measure a stray light characteristic of stray light from the beam not forward scattered by the droplet and measures a forward scattered light characteristic of light forward scattered by the droplet and further comprising an electronics system arranged to receive information from the detection system, the electronics system being configured to generate an indication of the presence of the droplet at the position based on a homodyne method using the stray light characteristic and the forward scattered light characteristic. The illumination system, the detection system, and the occlusion may or may not be collinear along a common optical axis. The optical axis of the illumination system forms an angle of not less than 0° and not greater than 90° with an optical axis of the detection system.

The apparatus may further comprise a pair of pellicles positioned at the first aperture.

The detection system may be a first detection system and the apparatus may further comprise a second detection system circumferentially displaced from the first detection system along a circumference of the tube-like element. The first detection system may be adapted to detect radiation having a first characteristic and the second detection system may be adapted to detect radiation having a second characteristic. The first characteristic may be a first wavelength and the second characteristic is a second wavelength. The first wavelength may be the same as the second wavelength. The first wavelength may be different from the second wavelength. The first characteristic may be a first polarization and the second characteristic may be a second polarization. The first polarization may be the same as the second polarization. The first polarization may be different from the second polarization.

According to another aspect of an embodiment there is disclosed a method of detecting a droplet of target material for generating extreme ultraviolet radiation, the method comprising illuminating with a beam of radiation a position in a trajectory of the droplet between a droplet generator and an irradiation region, detecting radiation from the beam forward scattered by the droplet when the droplet traverses the position, and determining a characteristic of the droplet based at least in part on the radiation forward scattered by the droplet. Determining a characteristic of the droplet may comprise determining the droplet's position. Determining a characteristic of the droplet may comprise determining the droplet's size. Determining a characteristic of the droplet may comprise determining the droplet's trajectory.

The method may further comprise detecting unscattered radiation from the beam determining a characteristic of the droplet may comprise determining a characteristic of the droplet based at least in part on the radiation forward scattered by the droplet and the unscattered radiation from the beam using a homodyne method. Determining a characteristic of the droplet may comprise determining the droplet's position, size, and/or trajectory. Determining the droplet characteristic based at least in part on the radiation forward scattered by the droplet and the unscattered radiation from the beam using a homodyne method may comprise using a detector. The detector may be part of a beam dump.

According to another aspect of an embodiment there is disclosed an apparatus for detecting a droplet of target material, the target material being used for generating extreme ultraviolet radiation in an irradiation region, the apparatus comprising an illumination system arranged to illuminate with a beam of radiation a position in a trajectory of the droplet between a droplet generator and the irradiation region and a detection system arranged to receive and adapted to detect radiation side scattered by the droplet when the droplet traverses the position.

The detection system may generate a signal indicative of a presence of the droplet at the position based on detecting the radiation side scattered by the droplet when the droplet reaches the position. The illumination system may comprise a laser.

The apparatus may further comprise a beam dump arranged to receive stray light from the detection system. The beam dump may comprise a sensor arranged to measure a characteristic of stray light and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.

The optical axis of the illumination system and an optical axis of the detection system may be substantially orthogonal.

The apparatus may further comprise a stray light control system positioned parallel to an optical axis of at least one of the illumination system and the detection system to impede propagation of stray light.

An optical axis of the illumination system may form an angle of not less than 0° and not greater than 90° with an optical axis of the detection system. The optical axis of the illumination system may form an angle of not less than 25° and not greater than 90° with an optical axis of the detection system.

According to another aspect of an embodiment there is disclosed an apparatus for detecting a droplet of target material, the target material being used for generating extreme ultraviolet radiation in an irradiation region, the droplet being generated by a droplet generator, the apparatus comprising an illumination system arranged to illuminate with a beam of radiation a position in a trajectory of the droplet between a nozzle of the droplet generator and the irradiation region, the illumination system arranged at a first aperture in a tube-like element arranged circumferentially around the position, and a detection system arranged at a second aperture in the tube-like element to receive radiation side scattered by the droplet when the droplet traverses the position.

The droplet of target material may be a part of a stream of droplets of target material, the tube-like element at least partially circumferentially surrounding a portion of the stream.

The illumination system may comprise a laser. The illumination system may have a first optical axis and the detection system may have a second optical axis and the first optical axis and the second optical axis may be substantially orthogonal.

The detection system may comprise a detector spaced apart from the position in a first direction along the second optical axis and a beam dump spaced away from the position in a second direction along the second optical axis, the second direction being opposite to the first direction. The beam dump may comprise a sensor arranged to measure a characteristic of stray light and be adapted to generate a stray light signal indicative of the characteristic and the apparatus may comprise an electronics system arranged to receive a detection signal from the detection system, the electronics system being configured to generate an indication of the presence of the droplet at the position based on a homodyne method using the detection signal and the stray light signal.

The apparatus may further comprise a first plurality of stray light containment structures positioned along the second optical axis between the detector and the position. The apparatus may further comprise a second plurality of stray light containment structures positioned along the second optical axis between the beam dump and the position.

An optical axis of the illumination system may form an angle of not greater than 90° with an optical axis of the detection system.

The detection system may be a first detection system and the apparatus may further comprise a second detection system circumferentially displaced from the first detection system along a circumference of the tube-like element. The first detection system may be adapted to detect radiation having a first characteristic and the second detection system may be adapted to detect radiation having a second characteristic. The first characteristic may be a first wavelength and the second characteristic may be a second wavelength. The first wavelength may be the same as the second wavelength. The first wavelength may be different from the second wavelength. The first characteristic may be a first polarization and the second characteristic may be a second polarization. The first polarization may be the same as the second polarization. The first polarization may be different from the second polarization.

According to another aspect of an embodiment there is disclosed a method of detecting a droplet of target material for generating extreme ultraviolet radiation, the method comprising illuminating with a beam of radiation a position in a trajectory of the droplet between a droplet generator and an irradiation region, detecting radiation from the beam side scattered by the droplet when the droplet traverses the position, and determining a characteristic of the droplet based at least in part on the radiation side scattered by the droplet.

Determining a characteristic of the droplet may comprise determining the droplet's position. Determining a characteristic of the droplet may comprise determining the droplet's size. Determining a characteristic of the droplet may comprise determining the droplet's trajectory.

The method may further comprise detecting unscattered radiation from the beam and determining a characteristic of the droplet may comprise determining a characteristic of the droplet based at least in part on the radiation side scattered by the droplet and the unscattered radiation from the beam using a homodyne method. Determining a characteristic of the droplet may comprise determining the droplet's position. Determining a characteristic of the droplet may comprise determining the droplet's size. Determining a characteristic of the droplet may comprise determining the droplet's trajectory. Determining the droplet characteristic based at least in part on the radiation side scattered by the droplet and the unscattered radiation from the beam using a homodyne method may comprise using a detector.

According to another aspect of an embodiment there is disclosed a method of detecting a droplet of target material for generating extreme ultraviolet radiation, the method comprising illuminating with a beam of radiation a position between a droplet generator and an irradiation region and detecting a presence of a droplet at the position by detecting radiation from the beam side scattered by the droplet when the droplet traverses the position.

The method may further comprise determining a characteristic of the droplet based at least in part on the radiation side scattered by the droplet. The characteristic may be a position along a trajectory of a droplet stream emanating from the droplet generator.

Further embodiments, features, and advantages of the subject matter of the present disclosure, as well as the structure and operation of the various embodiments are described in detail below with reference to accompanying drawings.

### BRIEF DESCRIPTION OF THE DRAWINGS

FIG. 1 is a schematic, not-to-scale view of an overall broad conception for a laser-produced plasma EUV radiation source system.

FIG. 2 is a schematic, not-to-scale view of a target material metrology system.

FIG. 3 is a schematic, not-to-scale view of a target material delivery system.

FIG. 4 is a diagram illustrating certain principles of target material stream break up and droplet coalescence.

FIG. 5 is a diagram illustrating certain principles of brightfield target material detection.

FIG. 6 is a partially schematic, not-to-scale block diagram of a system for detecting a target material droplet according to an aspect of an embodiment.

FIG. 7 is a partially schematic, not-to-scale block diagram of a system for detecting a target material droplet according to an aspect of an embodiment.

FIG. 8 is a flow chart of a method of detecting a target material droplet according to an aspect of an embodiment.

FIG. 9 is a flow chart of a method of detecting a target material droplet according to an aspect of an embodiment.

FIG. 10 is a partially schematic, not-to-scale block diagram of a system for detecting a target material droplet according to an aspect of an embodiment.

FIG. 11 is a partially schematic, not-to-scale block diagram of a system for detecting a target material droplet according to an aspect of an embodiment.

FIG. 12A is a partially schematic, not-to-scale block diagram of a system for controlling dispersal of stray light according to an aspect of an embodiment.

FIG. 12B is a cross section taken along line BB of FIG. 12A according to an aspect of an embodiment.

FIG. 13 is a partially schematic, not-to-scale block diagram of a system for detecting a target material droplet. the system including a system for controlling dispersal of stray light according to an aspect of an embodiment.

FIG. 14 is a flow chart of a method of detecting a target material droplet according to an aspect of an embodiment.

FIG. 15 is a flow chart of a method of detecting a target material droplet according to an aspect of an embodiment.

Further features and advantages of various embodiments, as well as the structure and operation of various embodiments, are described in detail below with reference to the accompanying drawings. It is noted that teachings contained herein are not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below.

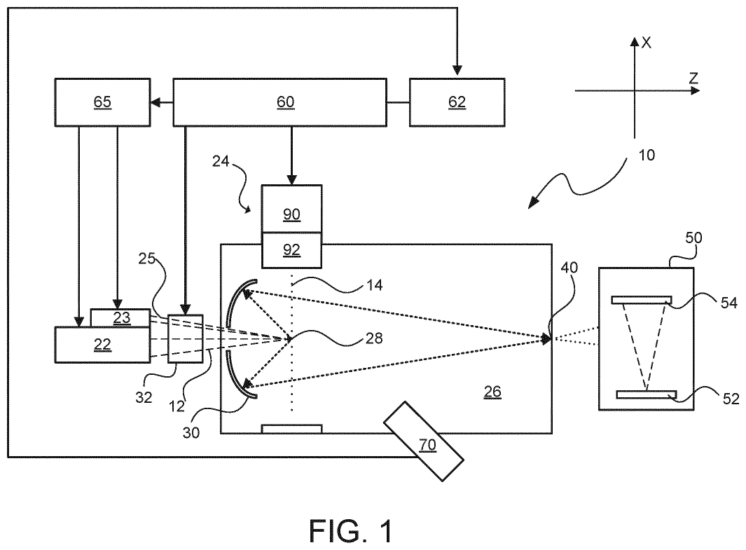

With initial reference to FIG. 1, there is shown a schematic view of an exemplary EUV radiation source, e.g., a laser produced plasma EUV radiation source 10 according to one aspect of an embodiment of the presently disclosed subject matter. As shown, the EUV radiation source 10 may include a pulsed or continuous laser source 22, which may for example be a pulsed gas discharge CO₂ laser source producing a beam 12 of radiation at a wavelength generally below 20 μm, for example, in the range of about 10.6 μm or to about 0.5 μm or less. The pulsed gas discharge CO₂ laser source may have DC or RF excitation operating at high power and at a high pulse repetition rate. The EUV radiation source 10 may also include one or more modules such as a conditioning laser 23 emitting a beam 25 of conditioning radiation as explained above.

The EUV radiation source 10 also includes a target delivery system 24 for delivering target material in the form of liquid droplets or a continuous liquid stream. In this example, the target material is a liquid, but it could also, for example, be a solid. The target material may be made up of tin or a tin compound, although other materials could be used. In the system depicted the target material delivery system 24 introduces the droplets 14 of the target material into the interior of a vacuum chamber 26 to an irradiation region 28 where the target material may be irradiated to produce plasma. In some cases, an electrical charge is placed on the target material to permit the target material to be steered toward or away from the irradiation region 28. It should be noted that as used herein an irradiation region is a region where target material irradiation is to occur and is an irradiation region even at times when no irradiation is actually occurring. The EUV light source may also include a beam focusing and steering system 32.

In the system shown, the components are arranged so that the droplets 14 travel substantially horizontally. The direction from the laser source 22 towards the irradiation region 28, that is, the nominal direction of propagation of the beam 12, may be taken as the Z axis. The path the droplets 14 take from the target material delivery system 24 to the irradiation region 28 may be taken as the X axis. The view of FIG. 1 is thus normal to the XZ plane. Also, while a system in which the droplets 14 travel substantially horizontally is depicted, it will be understood by one having ordinary skill in the art that other arrangements can be used in which the droplets travel vertically or at some angle with respect to gravity between and including 90° (horizontal) and 0° (vertical).

The EUV radiation source 10 may also include an EUV light source controller system 60, which may also include a laser firing control system 65, along with the beam steering system 32. The EUV radiation source 10 may also include a detector such as a target position detection system which may include one or more droplet imagers 70 that generate an output indicative of the absolute or relative position of a target droplet, e.g., relative to the irradiation region 28, and provide this output to a target position detection feedback system 62.

The target position detection feedback system 62 may use the output of the droplet imager 70 to compute a target position and trajectory, from which a target error can be computed. The target error can be computed on a droplet-by-droplet basis, or on average, or on some other basis. The target error may then be provided as an input to the EUV light source controller 60. In response, the EUV light source controller 60 can generate a control signal such as a laser position, direction, or timing correction signal and provide this control signal to the laser beam steering system 32. The laser beam steering system 32 can use the control signal to change the location and/or focal power of the laser beam focal spot within the chamber 26. The laser beam steering system 32 can also use the control signal to change the geometry of the interaction of the beam 12 and the droplet 14. For example, the beam 12 can be made to strike the droplet 14 off-center or at an angle of incidence other than directly head-on.

As shown in FIG. 1, the target material delivery system 24 may include a target delivery control system 90. The target delivery control system 90 is operable in response to a signal, for example, the target error described above, or some quantity derived from the target error provided by the system controller 60, to adjust the paths of the target droplets 14 through the irradiation region 28. This may be accomplished, for example, by repositioning the point at which a target delivery mechanism 92 releases the target droplets 14. The droplet release point may be repositioned, for example, by tilting the target delivery mechanism 92 or by shifting the target delivery mechanism 92. The target delivery mechanism 92 extends into the chamber 26 and is preferably externally supplied with target material and with gas from a gas source to place the target material in the target delivery mechanism 92 under pressure.

Continuing with FIG. 1, the radiation source 10 may also include one or more optical elements. In the following discussion, a collector 30 is used as an example of such an optical element, but the discussion applies to other optical elements as well. The collector 30 may be a normal incidence reflector, for example, implemented as a multilayer mirror (MLM) fabricated by depositing many pairs of Mo and Si layers on a substrate with additional thin barrier layers, for example B₄C, ZrC, Si₃N₄ or C, deposited at each interface between layer pairs to effectively block thermally-induced interlayer diffusion, but the collector 30 may be formed of other layers of material in other embodiments. The collector 30 may be in the form of a prolate ellipsoid, with a central aperture to allow the laser beam 12 to pass through and reach the irradiation region 28. The collector 30 may be, e.g., in the shape of an ellipsoid that has a first focus at the irradiation region 28 and a second focus at a so-called intermediate point 40 (also called the intermediate focus 40) where the EUV radiation may be output from the EUV radiation source 10 and input to, e.g., an integrated circuit lithography scanner or stepper 50. The scanner or stepper 50 uses the radiation, for example, to process a silicon wafer workpiece 52 in a known manner using a reticle or mask 54. The silicon wafer workpiece 52 is then additionally processed in a known manner to obtain integrated circuit devices.

As mentioned, in general, for a reference coordinate system, Z is the direction along which the laser beam 12 propagates and is also the direction from the collector 30 to the irradiation site 28 and the EUV intermediate focus 40. X is in the droplet propagation plane. Y is orthogonal to the XZ plane. To make this a right-handed coordinate system, the trajectory of the droplets 14 is taken to be in the −X direction.

In the example shown, the target material 14 is in the form of a stream of droplets released by a target material dispenser 92, which in the example is a droplet generator. The target material droplet 14 can be ionized by a main pulse in this form. Alternatively, the target material 14 can be preconditioned for ionization with a conditioning pulse 25 that can, for example, change the geometric distribution of the target material 14. Thus, it may be necessary both to hit the target material 14 accurately with the conditioning pulse to ensure the target material 14 is in the desired form (disk, cloud, etc.), and to hit the target accurately with the main pulse to promote efficient production of EUV radiation.

As used herein, the term “irradiation site” is used to connote the position 28 in the chamber 26 where the target material 14 is struck with a main pulse. It may coincide with the primary focus of the collector mirror 30.

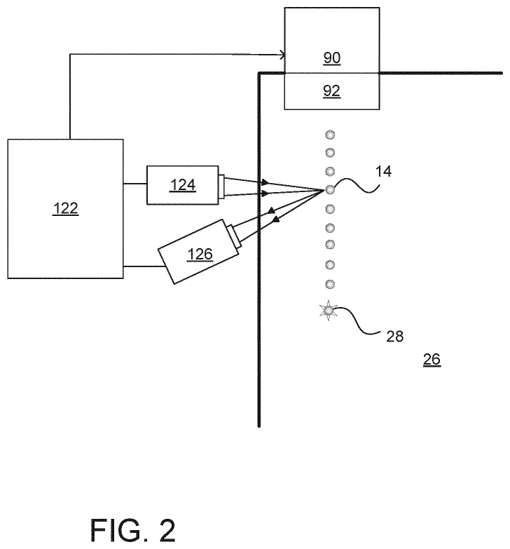

As mentioned, one droplet detection metrology utilizes darkfield illumination, where the backscatter from a droplet passing through a laser curtain is collected near the primary focus. The metrology device detects the droplet crossing at a specific location in space to provide a trigger to the system controls to enable all ensuing sequences to generate EUV light. An example of such a system is shown schematically in FIG. 2, in which a droplet detection controller 122 causes a droplet illumination module (DIM) 124 to illuminate a droplet 14. A droplet detection module (DDM) 126 detects the radiation backscattered by the droplet to permit the droplet detection controller 122 to derive information such as the position of the droplet 14. Note that herein, the form of the target material is referred to as a droplet even if one or more conditioning pulses have altered the target material from a true droplet form. The detection process described above in connection with FIG. 2 may be used to detect the droplets after they have fully coalesced from smaller droplets and tune the operation of the droplet generator.

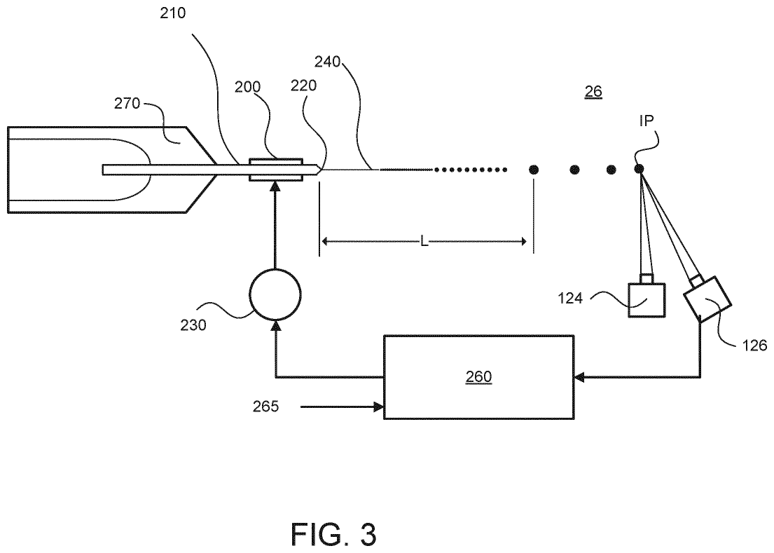

Referring now to FIG. 3, there is shown a capillary 210 terminating in a nozzle 220 and protruding from a nozzle body 270. An electro-actuatable element 200 is positioned around a lengthwise portion of the capillary 210. The electro-actuatable element 200 transduces electrical energy from a waveform generator 230 to apply varying pressure to a capillary 210. This introduces a velocity perturbation in the stream 240 of molten target material 240 exiting the capillary 210. The target material ultimately coalesces into droplets which are illuminated by the DIM 124 and imaged by the DDM 126. The term “imaged” as used herein encompasses both forming an image of the droplet as well as a mere binary indication of the presence or absence of a droplet. The imaging may be used to develop a velocity profile of the droplet stream at the imaging point IP. A control unit 260 may use the imaging data from the DDM 126 to generate a feedback signal to control operation of the wave generator 230 and tune operation of the droplet generator 24.

For clarity, droplet generator tuning refers to the process of adjusting certain operational parameters of the droplet generator to control its performance. The design of the droplet generator makes available certain “levers” that can be manipulated to control its operation. For example, as described more fully below, control of the drive waveform applied to the electro-actuatable element 200 can be used to control aspects of the droplet coalescence process. These aspects can be observed, such as the coalescence length L, the number of satellites, and the velocity profile of the droplet stream to determine whether operation of the droplet generator is satisfactory or whether it needs to be tuned to improve its performance by adjusting these operational parameters. The tuning is in-line when it can be performed without taking the droplet generator offline.

For example, the control means 260 may control the relative phase of the components of a hybrid driving signal applied to the electro-actuatable element 200, that is, a combination of a low frequency periodic component and a higher order periodic component. The control means 260 may also control the amplitude of the low frequency periodic component and the amplitude of the higher order periodic component. This control may be based on a control input 265 (see FIG. 3) which may originate from another controller or be based on a user input. The relative phase of the low frequency periodic component and the higher order periodic component may be adjusted to control the coalescence length L. The amplitude of the low frequency periodic component may be adjusted to control droplet coalescence. The amplitude of the higher order arbitrary periodic component may be adjusted to control droplet velocity jitter.

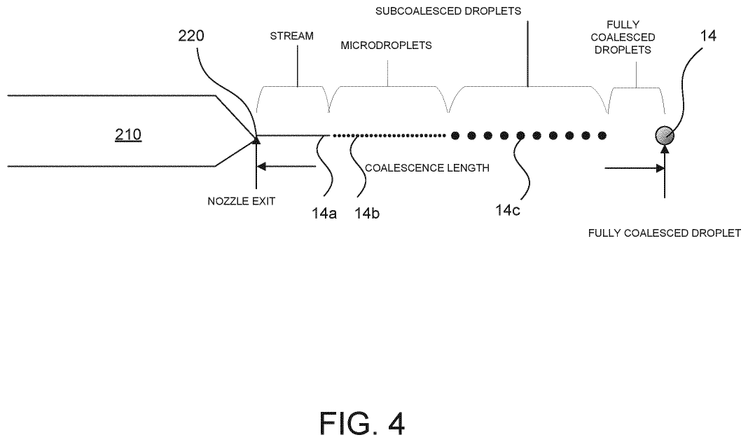

The imposition of the hybrid waveform described above decomposes the overall droplet coalescence process into a succession of subcoalescence steps or regimes evolving as a function of distance from the nozzle 220. FIG. 4 illustrates these principles. It should be noted that the difference in the relative sizes of the capillary 210 and the droplets 14 has been greatly reduced in FIG. 4 for simplification. For example, in a first regime, that is, when the target material first exits the nozzle 220, the target material is in the form of a velocity-perturbed steady stream 14a. In a second regime, the stream 14a breaks up into a series of microdroplets 14b having varying velocities. In the third regime, measured either in time of flight or by distance from the nozzle 220, the microdroplets 14b coalesce into droplets of an intermediate size, referred to as subcoalesced droplets 14c, having varying velocities with respect to one another. In the fourth regime the subcoalesced droplets 14c coalesce into droplets 14 having the desired final size. The number of subcoalescence steps can vary. The distance from the nozzle 220 to the point at which the droplets reach their final coalesced state is the coalescence length L. In the coalescence process, there may be droplets that do not coalesce with others. These are referred to as satellite droplets.

In general, an arrangement such as that shown in FIG. 2 can detect satellites as small as around 7 μm diameter and enable some amount of droplet generator tuning capability to optimize performance of the droplet generator. As described below, in accordance with an aspect of an embodiment, a system is provided that has a lower detection limit so that smaller satellites and smaller subcoalesced droplets may be observed. This provides additional data for tuning of the droplet generator and the waveform applied to the droplet generator to optimize target material stream break up and coalescence, for example, to minimize the production of satellites and obtain a desired velocity profile.

As mentioned, the DIM/DDM layout and measurement location have several disadvantages limiting their droplet detection capability. Due to the layout of the vessel 26, the DIM 124 and the DDM 126 (FIGS. 2 and 3) must be positioned at a substantial distance away from the measurement plane. This distance reduces the numerical aperture of the collection optics and limits how tightly the DIM 124 can be focused. It also necessitates the use of a relatively high-power illumination laser (on the order of about 50 W).

One possibility for avoiding these disadvantages is deploying a droplet detection device utilizing brightfield illumination to enable droplet generator inline tuning. Such a device measures the loss of signal that results from obscuration from a droplet passing through a laser curtain near the droplet generator nozzle. Such a system would render data comparable to that provided by the system described above using DIM and DDM, with an added benefit of permitting incorporation of a homodyne detection system that enables laser noise subtraction.

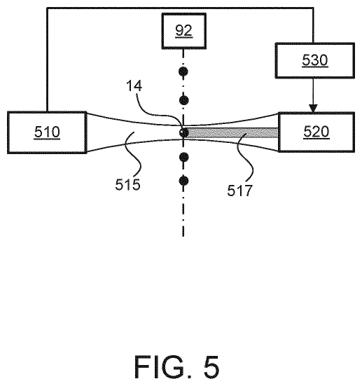

Implementation of a brightfield illumination approach, however, entails a direct tradeoff between field of view versus minimum droplet size detection capability as shown in FIG. 5. In the arrangement shown in FIG. 5, a droplet generator 92 emits a stream of droplets 14. A light source 510, which in this example is a laser, establishes a laser curtain 515 that illuminates the droplets and a detector 520 receives the light from the light source 510 as partially blocked by the droplet 14. A power monitor 530 controls the amount of illumination generated by the light source 510. The brightfield approach is thus measuring a shadow 517 of the droplet 14, which is equivalently represented as the percent obscuration of the laser curtain 515 by the droplet 14. To increase the field of view, the cross-sectional area of the laser curtain 517 of the must be increased, and therefore the percent obscuration of a given droplet size will decrease. This makes it more difficult to detect smaller droplets such as microdroplets 14b and subcoalesced droplets 14c. This fundamentally limits the scalability of this brightfield illumination approach, regardless of the wavelength and source power used.

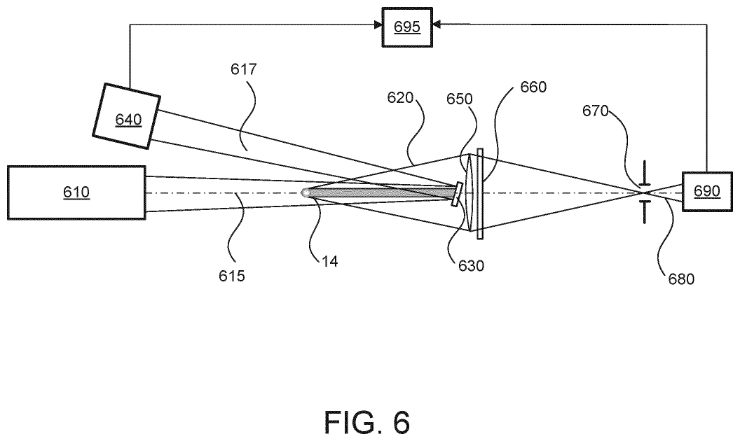

To avoid this limitation and to provide for other advantages, according to an aspect of an embodiment, darkfield illumination is used to measure the partially-obscured forward scatter from a droplet 14. As shown in FIG. 6, a light source 610, which may be a laser, generates a beam 615 that illuminates a droplet 14 which is traversing the beam 615 as the droplet 14 travels to the irradiation region. In the orientation shown in FIG. 6, the droplet 14 is moving orthogonal to the plane of the figure. Illumination of the droplet 14 results in a cone of forward scattered light 620. The illumination beam 615 after being partially blocked by the droplet 14 is then blocked by a small mirror obscuration 630. The light that is reflected by the small mirror obscuration 630 is disposed of in a beam dump/sensor 640.

The cone of forward scattered light 620 passes through a condensing lens 650 and a bandpass and/or polarization filter 660. The bandpass and/or polarization filter 660 blocks light from other sources. The forward scattered light 620 then propagates to an aperture 670 arranged to block stray light from other sources such as the beam dump/sensor 640. Here and elsewhere, the term “stray light” is used to connote light not scattered by the droplet 14 but instead scattered by other surfaces within the chamber.

The forward scattered light 620 reaches a sensor 690 which uses the forward scattered light 620 to detect when the droplet 14 has crossed the beam 615. As will be noted in the “darkfield” illumination arrangement, there is essentially no light reaching the sensor 690 until a droplet 14 forward scatters some of the light thus permitting some light to bypass the obstruction 630. Thus, “no light” at the sensor 690 indicates that there is no droplet 14 in the beam 615 while “light” at the sensor 690 indicates that there is a droplet 14 in the beam 615.

Stray light can be used to derive a reference signal that may be employed by a homodyne detector 695 to perform homodyne detection of the signal indicating the droplet 14 crossing the beam 615. The signal from the beam dump/sensor 640 can also or alternatively be used to derive a reference signal for homodyne detection.

In this implementation, the sensor 690 is aligned along an optical axis of the light source 610 (0°) such that the forward scattered light 620 from the droplets 14 is collected. An obscuration such as the small mirror obscuration 630 is necessary to block the light from the light source 610 from directly entering the sensor 690. In this example the small mirror obscuration 630 is a tilted reflecting surface that redirects the light to the sensor acting as beam dump/sensor 640 in a beam 617. The sensor 640 could be used to derive a laser noise signal from the beam 617 which could be subtracted from the detection signal developed by the sensor 690 to enable noise cancellation from, e.g., stray laser light reaching the sensor 690.

In an arrangement such as that shown in FIG. 6, the detector can be placed closer to the droplet detection point. This makes it possible to increase the numerical aperture of the collection optics and relieves limitations on how tightly the light source can be focused, making it possible to use a lower power illumination laser. Also, the detection point can be placed closer to the exit of the nozzle 220 (FIG. 3) of the droplet generator, making it possible to observe subcoalesced droplets and so to facilitate droplet generator inline tuning.

Also, more light, and, hence, more signal is available when detecting forward scattered light. This advantage may become less pronounced as droplet size decreases. The forward scattering of the light becomes broader (light smeared out to larger angles between 0-90°) as droplet size decreases towards the wavelength of light (˜1-2 μm). Backscatter, on the other hand, increases as the droplet size becomes much smaller than the wavelength of the light. Nevertheless, the use of forward scattered light in connection with droplet sizes of interest, e.g., (˜1-27 μm) still yields a considerable advantage over the use of back scattered light in terms of the amount of available signal.

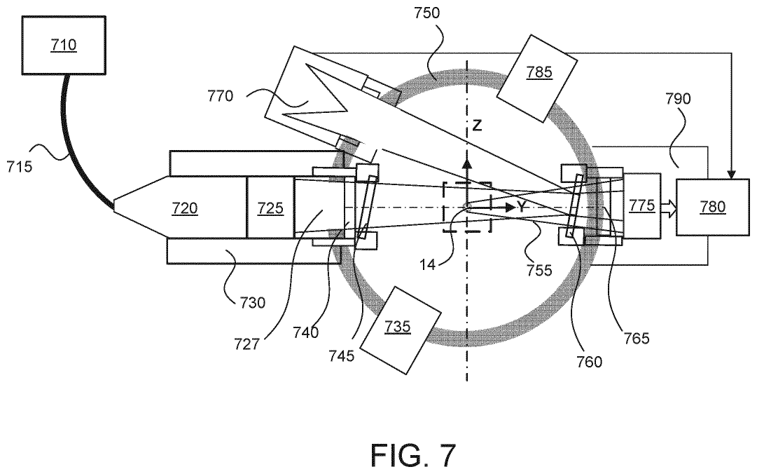

Another example of an implementation in accordance with an aspect of an embodiment is shown in FIG. 7. As shown in FIG. 7, a light source 710, which may be a laser module, generates illumination which is carried by a fiber optic cable 715 to a collimating optics module 720 located in an enclosure 730 along with a beam shaping module 725. The light from the collimating optics module 720 is conveyed to the beam shaping optics module 725. A beam 727 from the beam shaping module 725 then passes through a pair of pellicles 740 and 745 in a first aperture into an interior of a droplet generator tubelike member 750 that at least partially surrounds and extends partially along the droplet trajectory orthogonal to the plane of the figure. Inside the droplet generator tubelike member 750, the beam 727 is interrupted by a droplet 14. The interruption caused by the droplet 14 results in a cone of forward scattered light 755 travelling toward an imaging optics module 775. This cone of forward scattered light 755 strikes a pellicle 760 having a central reflective portion which obscures a central part of the illuminating beam 727 and reflects it to a beam dump 770. The forward scattered light 755 then passes through a second pellicle 765 in a second aperture in the droplet generator tubelike member 750 into a detector system including the imaging the optics module 775 inside an enclosure 790. The imaging optics module 775 conveys the image to an electronics module 780.

The arrangement of FIG. 7 shows the illumination system and the detector in a collinear arrangement, that is, in which the angle between the illumination beam emitted by the illumination system and the detector is essentially 0°. It will be apparent to one of ordinary skill in the art that the detector could also be arranged off-axis as indicated by inclusion of a detector 785. Also, more than one detector could be used in which case the detector including the imaging optics module 775 and the detector 785 could be used simultaneously. The detectors could detect light having the same characteristics in terms of, for example, wavelength and polarization or they could be adapted to detect light having different characteristics. In other words, one detector could be arranged to detect light having a first wavelength and/or a first polarization and the other detector could be adapted to measure light having a second wavelength different from the first wavelength and/or a second polarization different from the first polarization. In the same vein, multiple light sources may be used as indicated by inclusion of a light source 735. The light source 735 may emit a beam having the same characteristics as the illumination beam 727 emitted by the beam shaping optics module 725, for example, the same wavelength and polarization, or the wavelength and polarization of the beam emitted by light source 735 may be different from those of the illumination beam 727 emitted by the beam shaping optics module 725.

A benefit of using darkfield illumination is the scalability of detection size and field of view with power. The effects of field of view scaling (irradiance reduction on-droplet) can be compensated with higher laser power. Similarly, smaller droplets can be detected by using higher laser power. In addition, Mie scattering analysis indicates a factor of approximately 10×-20× improvement in signal level for droplet detection using forward scattered light. Detection of droplets having sizes of about 2 μm can be achieved utilizing forward scatter collection with an obscuration.

Another benefit of this approach is to increase the amount of measured signal available for a given laser power, thereby improving the signal-to-noise ratio and consequently minimum droplet size detection capability. A consideration for the darkfield illumination approach is signal-to-noise ratio, where the main noise contributor can be stray light from the laser reaching the detector. It is therefore desirable to have a high droplet scattering efficiency to ensure a high signal-to-noise ratio. The additional amount of signal may enable reducing the required laser power, which may open up the possibility of using additional types of lasers such as telecommunications grade lasers that are highly stable, highly reliable, and cost less as the illumination sources.

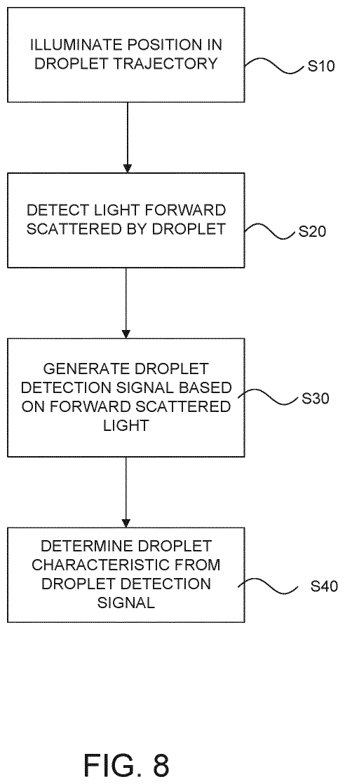

FIG. 8 is a flow chart showing a method implemented in accordance with an aspect of an embodiment. As shown in FIG. 8, in a step S10 a position in the expected trajectory of a droplet of target material is illuminated. This can be accomplished, for example, by the use of a laser. Then in a step S20 the light forward scattered by the droplet is detected. In a step S30 a droplet detection signal is generated based on light from the beam forward scattered by the droplet. In a step S40 a characteristic of the droplet is determined from the droplet detection signal. Here, determining the characteristic of the droplet could include, for example, detecting one or more of the presence of the droplet at a position within the beam of illumination, the droplet's position, the droplet's size, the droplet's trajectory, or any other determination possible from the data obtained through the droplet detection.

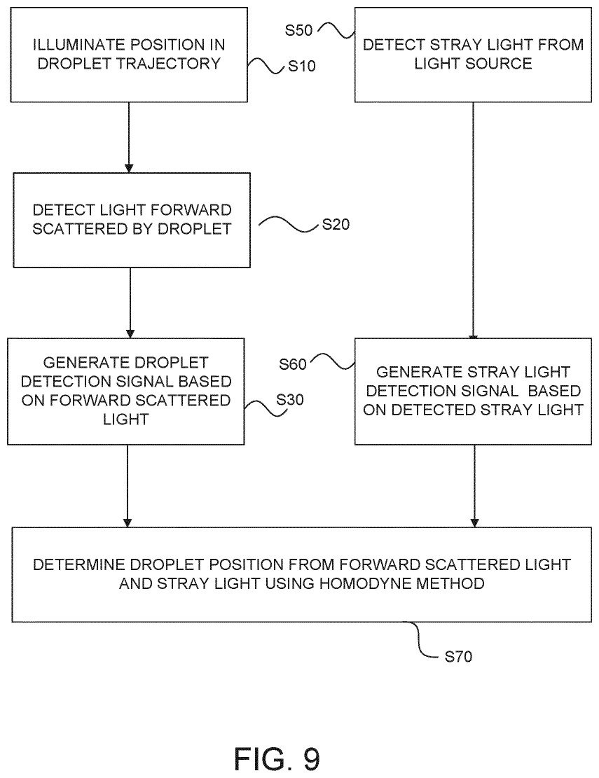

FIG. 9 is also a flow chart showing a method implemented in accordance with an aspect of an embodiment. As shown in FIG. 9, in a step S10 a position in the expected trajectory of a droplet of target material is illuminated. This can be accomplished, for example, by the use of a laser. Then in a step S20 the light forward scattered by the droplet is detected. In a step S30 a droplet detection signal is generated based on light from the beam forward scattered by the droplet. Concurrently or at least sufficiently concurrently that the data is timely available, in a step S50 stray light from the illumination source is also detected. This can be accomplished, for example, using a beam dump sensor. In a step S60 a stray light signal is generated using the stray light detection. In a step S70 a characteristic of the droplet is determined based on the droplet detection signal and the stray light signal using a homodyne method by combining the two signals, e.g., subtracting the signal from the stray light from the signal from the forward scattered light. Here, determining the characteristic of the droplet again could include, for example, detecting one or more of the presence of the droplet at a position within the beam of illumination, the droplet's position, the droplet's size, the droplet's trajectory, or any other determination possible from the data obtained through the droplet and stray light detection.

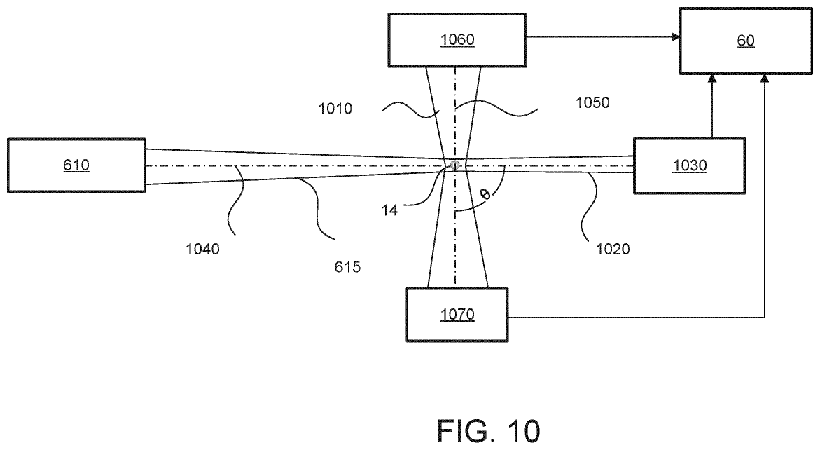

According to another aspect of an embodiment, darkfield illumination is used to measure the side scatter from a droplet 14. As used herein, “side scatter” and “side scattered” and similar terms refer to light scattered by the droplet in a direction having a primary component orthogonal to the direction of the illumination beam, e.g., at an angle to the illumination beam of about 90° and including angles, for example, in a range from about 45° to about 90° with respect to the forward direction of the illumination beam, with “about” meaning within conventional tolerances. As shown in FIG. 10, a light source 610, which may be a laser, generates an illumination beam 615 that illuminates a droplet 14 which is traversing the illumination beam 615 as the droplet 14 travels towards the irradiation region. In the orientation shown in FIG. 10, the droplet 14 is moving orthogonal to the plane of the figure. The droplet 14 scatters some portion of the illumination beam 615, travelling along the illumination optical axis 1040, sideways along a detection optical axis 1050. The detection optical axis 1050 is at an angle θ with respect to the illumination optical axis 1040 in the direction of propagation of the illumination beam 615. In other words, illumination of the droplet 14 results in a side scattered beam portion 1010. The unblocked portion of the illumination beam 615, i.e., beam 1020, is trapped by a beam dump 1030. The beam dump 1030 may be provided with metrology capabilities as described more fully below.

The side scattered beam portion 1010 propagates to a detector 1060 which uses the side scattered light 1010 to detect a characteristic of the droplet 14, e.g., when the droplet 14 has crossed the beam 615. As will be noted in the “darkfield” illumination arrangement, there is essentially no light reaching the sensor 1060 until a droplet 14 side scatters some of the light thus permitting some light to propagate sideways. Thus, “no light” at the detector 1060 indicates that there is no droplet 14 in the beam 615 while “light” at the detector 1060 indicates that there is a droplet 14 in the beam 615. Stray light propagating along the detection optical axis is trapped by a detection light dump 1070. The detection light dump 1070 may be provided with metrology capabilities as described more fully below.

The description above is in terms of the detector 1060 being drawn above the droplet 14 merely for illustration purposes. It will be understood that the orientation in the figure is arbitrary and that the detector could also be illustrated as being below the droplet 14 or directly in front of or behind the droplet 14. It will also be understood that it is not necessary that the optical axis of the detector 14 need not necessarily be orthogonal to the direction of propagation of the illumination beam 614.

The signal from the detector 1060 is provided to a controller such as the EUV light source controller 60. The EUV light source controller 60 uses the signal to determine, for example, the position and/or timing of the droplet 14. Also, as shown, the illumination beam dump 1030 and/or the detection beam dump 1070 can be provided with detectors and sensors to provide data to the EUV light source controller 60. For example, the illumination beam dump 1030 if provided with a sensor can obtain a measurement indicating the power of the illumination laser beam 615 which may be used to determine the health of the light source 610. The detection light dump 1070 if provided with a sensor can be used to obtain a measurement of stray light which can be used to derive a reference signal that in turn may be employed by a homodyne detector to perform homodyne detection of the signal indicating the droplet 14 crossing the beam 615. The sensors could be used to derive a laser noise signal from the detection light dump 1070 which could be subtracted from the detection signal developed by the detector 1060 to enable noise cancellation from, e.g., stray laser light reaching a sensor in the detection light dump 1070.

In this implementation, the sensor 1060 is aligned along the detection optical axis 1050 which is about orthogonal to the illumination optical axis 1040 optical axis of the light source 610 such that the side scattered light 1010 from the droplets 14 is collected.

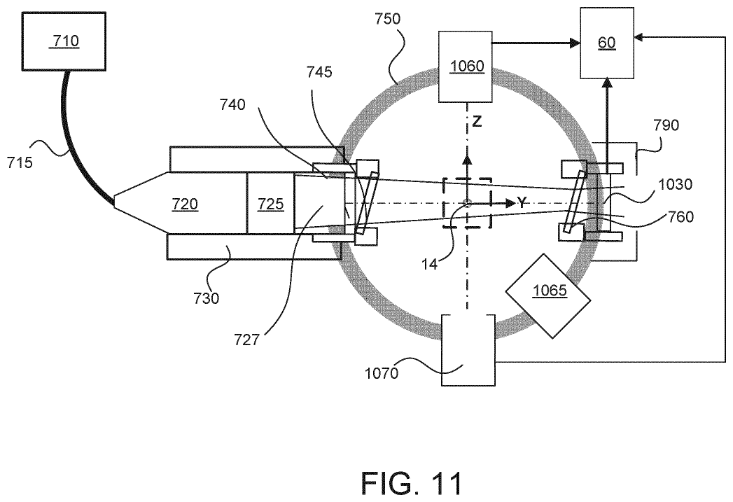

Another example of an implementation in accordance with an aspect of an embodiment is shown in FIG. 11. As shown in FIG. 11, a light source 710, which may be a laser module, generates illumination which is carried by a fiber optic cable 715 to a collimating optics module 720 located in an enclosure 730 along with a beam shaping module 725. The light from the collimating optics module 720 is conveyed to the beam shaping optics module 725. A beam 727 from the beam shaping module 725 then passes through a pair of pellicles 740 and 745 in a first aperture into an interior of a droplet generator tubelike member 750, which may for example, comprise target material shielding baffles, that at least partially surrounds and extends partially along the droplet trajectory orthogonal to the plane of the figure. Inside the droplet generator tubelike member 750, the beam 727 is interrupted by a droplet 14. The interruption caused by the droplet 14 results in side-scattered light travelling towards the detector 1060. The unblocked light strikes a pellicle 760 and then propagates to the illumination beam dump 1030 in an enclosure 790. The illumination beam dump 1030 may include a sensor which conveys metrology data to the EUV light source controller 60. The side scattered beam propagates to the detector 1060 which generates a droplet detection signal to the EUV light source controller 60. Stray light, i.e., light other than light side scattered from the droplet to the detector 1060 such as light reflected from structures inside the tubelike member 750 propagates to the detection beam dump 1070. As mentioned, the illumination beam dump 1030 may also include a sensor which conveys metrology data to the EUV light source controller 60.

The arrangement of FIG. 11 shows the illumination system and the detector in an orthogonal arrangement, that is, in which the angle between the illumination beam 727 and the optical axis of the detector 1060 is about 90°. It will be apparent to one of ordinary skill in the art that other detectors such as a detector 1065 could also be arranged off-axis. Multiple detectors could detect light having the same characteristics in terms of, for example, wavelength and polarization, or the multiple detectors could be adapted and arranged to detect light having different characteristics. In other words, one detector could be arranged to detect light having a first wavelength and/or a first polarization and the other detector could be adapted to measure light having a second wavelength different from the first wavelength and/or a second polarization different from the first polarization. In the same vein, multiple light sources or a light source emitting light with multiple characteristics may be used. Additional light sources may emit a beam having the same characteristics as the illumination beam 727 emitted by the beam shaping optics module 725, for example, the same wavelength and polarization, or the wavelength and polarization of the beam emitted by the additional light sources may be different from those of the illumination beam 727 emitted by the beam shaping optics module 725.

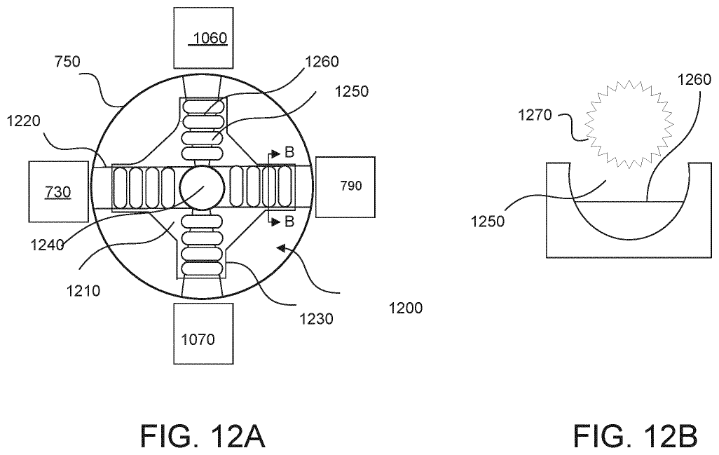

For some implementations it will be beneficial to employ measures directed to controlling the dispersal of stray light. FIG. 12A is a plan view diagram of a system 1200 for controlling stray light. The system 1200 includes a cruciform member 1210 having two arms 1220 and 1230 crossing in the droplet illumination region 1240. The arm 1220 defines a passage for the illumination beam and the arm 1230 defines a passage for the side scattered detection light. In the embodiment shown in FIG. 12A the system 1200 includes a linear array of cavities 1250 separated by ribs or baffles 1260 disposed in each arm. The combination of the cavities and baffles defines stray light containment structures that hinder the propagation of light in directions other than along the optical axes of the beams. In other words, light impinging on these stray light containment structures is scattered and its propagation impeded. FIG. 12B is a cross section of one of these stray light containment structures taken along line BB of FIG. 12A. A beam 1270 travels the stray light containment structure essentially unimpeded but the propagation of stray light is impeded. The stray light containment structures may be made by milling cavities with intervening ribs in the arms of 1220, 1230 of the cruciform member 1210.

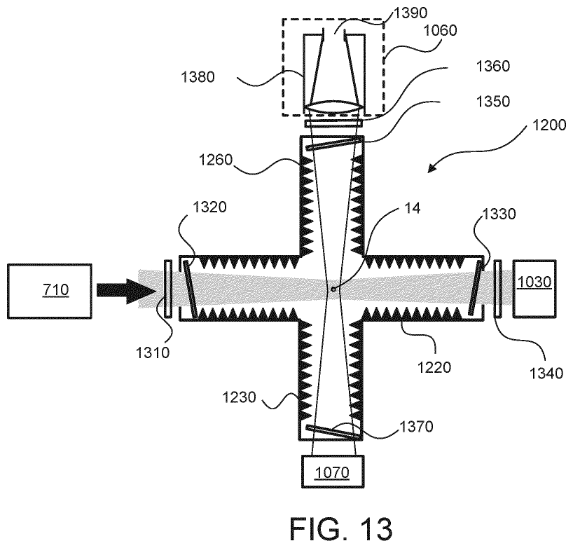

FIG. 13 is a diagram showing further features of the system 1200. Light from the light source 710 enters the system 1200 through a vacuum window 1310 and a pellicle 1320. According to an aspect of an embodiment, the pellicle 1320 and other pellicles in the system are slanted with respect to the optical axis of their respective arms as an additional measure to control the dispersal of stray light. The light then travels along arm 1220 to the droplet 14. Unblocked radiation then propagates to a pellicle 1330 and a vacuum window 1340 to reach beam dump 1030. Light side scattered by the droplet 14 travels upward in the drawing in the arm 1230 through a pellicle 1350 and a vacuum window 1360 to reach a detector 1060 including a detection optics tube 1380 and a detection optics slit 1390. Stray light in the arm 1230 travels to the detection light dump 1070 through a pellicle 1370. The sidewalls of the arms 1220, 1230 include an array of baffles 1260 as described above in connection with FIGS. 12A and 12B which limit the propagation of stray light.

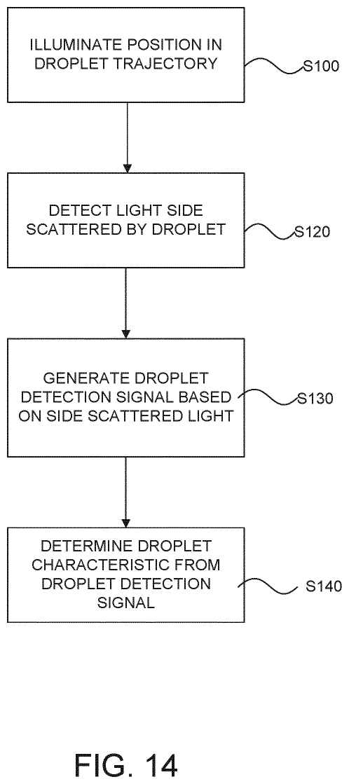

FIG. 14 is a flow chart showing a method implemented in accordance with an aspect of an embodiment. As shown in FIG. 14, in a step S100 a position in the expected trajectory of a droplet of target material is illuminated. This can be accomplished, for example, by the use of a laser. Then in a step S120 the light side scattered by the droplet is detected. In a step S130 a droplet detection signal is generated based on light from the beam side scattered by the droplet. In a step S140 a characteristic of the droplet is determined from the droplet detection signal. Here, determining the characteristic of the droplet could include, for example, detecting one or more of the presence of the droplet at a position within the beam of illumination, the droplet's position, the droplet's size, the droplet's trajectory, or any other determination possible from the data obtained through the droplet detection.

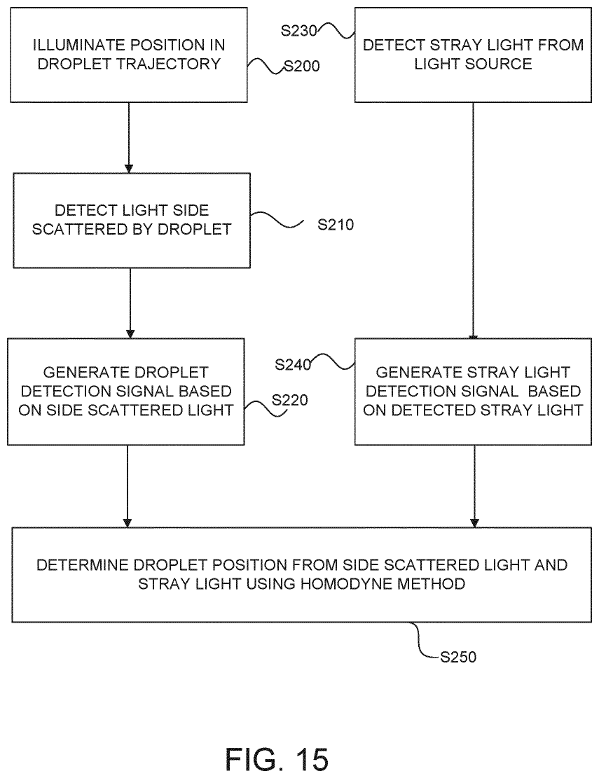

FIG. 15 is also a flow chart showing a method implemented in accordance with an aspect of an embodiment. As shown in FIG. 15, in a step S200 a position in the expected trajectory of a droplet of target material is illuminated. This can be accomplished, for example, by the use of a laser. Then in a step S210 the light side scattered by the droplet is detected. In a step S220 a droplet detection signal is generated based on light from the beam side scattered by the droplet. Concurrently or at least sufficiently concurrently that the data is timely available, in a step S230 stray light from the illumination source is also detected. This can be accomplished, for example, using a beam dump sensor. In a step S240 a stray light signal is generated using the stray light detection. In a step S250 a characteristic of the droplet is determined based on the droplet detection signal and the stray light signal using a homodyne method by combining the two signals, e.g., subtracting the signal from the stray light from the signal from the side scattered light. Here, determining the characteristic of the droplet could again include, for example, detecting one or more of the presence of the droplet at a position within the beam of illumination, the droplet's position, the droplet's size, the droplet's trajectory, or any other determination possible from the data obtained through the droplet and stray light detection.

It will be apparent to one of ordinary skill in the art that variations other than those expressly described above may be implemented without departing from the essential principles of the invention.

The present disclosure is made the aid of functional building blocks illustrating the implementation of specified functions and relationships thereof. The boundaries of these functional building blocks have been arbitrarily defined herein for the convenience of the description. Alternate boundaries can be defined so long as the specified functions thereof are appropriately performed.

The above description includes examples of one or more embodiments. It is, of course, not possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is construed when employed as a transitional word in a claim. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

The embodiments can be further described using the following clauses:

1. Apparatus for detecting a droplet of target material for generating extreme ultraviolet radiation in an irradiation region, the apparatus comprising:
an illumination system arranged to illuminate with a beam of radiation a position in a trajectory of the droplet between a droplet generator and the irradiation region;
a detection system arranged to receive and adapted to detect radiation forward scattered by the droplet when the droplet traverses the position; and
an occlusion arranged in an optical path between the position and the detection system to block the beam of radiation from directly reaching the detection system.
   2. The apparatus of clause 1 wherein the detection system generates a signal indicative of a presence of the droplet at the position based on detecting the radiation forward scattered by the droplet when the droplet reaches the position.
   3. The apparatus of clause 1 wherein the illumination system comprises a laser.
   4. The apparatus of clause 1 further comprising a beam dump and wherein the occlusion is reflective and reflects the beam to the beam dump.
   5. The apparatus of clause 4 wherein the beam dump comprises a sensor arranged to measure a characteristic of stray light from the beam not forward scattered by the droplet and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.
   6. The apparatus of clause 1 wherein the detection system measures a stray light characteristic of stray light from the beam not forward scattered by the droplet and measures a forward scattered light characteristic of light forward scattered by the droplet and further comprising an electronics system arranged to receive information from the detection system, the electronics system being configured to generate an indication of the presence of the droplet at the position based on a homodyne method using the stray light characteristic and the forward scattered light characteristic.
   7. The apparatus of clause 1 wherein the illumination system, the detection system, and the occlusion are collinear along a common optical axis.
   8. The apparatus of clause 7 further comprising an aperture positioned on the optical axis in front of the detection system to block at least some unscattered light originating from the illumination system from reaching the detection system.
   9. The apparatus of clause 8 further comprising a condensing lens arranged on the optical axis between the occlusion and the aperture to focus the forward scattered light at the aperture.
   10. The apparatus of clause 1 further comprising an optical filter arranged on the optical axis between the occlusion and detection system.
   11. The apparatus of clause 10 wherein the optical filter comprises a bandpass filter.
   12. The apparatus of clause 10 wherein the optical filter comprises a polarization filter.
   13. The apparatus of clause 1 wherein the illumination system, the detection system, and the occlusion are not collinear.
   14. The apparatus of clause 13 wherein an optical axis of the illumination system forms an angle of not less than 0° and not greater than 90° with an optical axis of the detection system.
   15. The apparatus of clause 13 wherein an optical axis of the illumination system forms an angle of not less than 25° and not greater than 90° with an optical axis of the detection system.
   16. The apparatus of clause 13 wherein the droplet is a coalesced droplet.
   17. The apparatus of clause 13 wherein the droplet is a subcoalesced droplet.
   18. The apparatus of clause 13 wherein the droplet is a microdroplet.
   19. The apparatus of clause 13 wherein the droplet is a satellite droplet.
   20. Apparatus for detecting a droplet in a stream of droplets of target material for generating extreme ultraviolet radiation in an irradiation region, the droplet being generated by a droplet generator comprising a tube-like element at least partially circumferentially surrounding a portion of the stream, the apparatus comprising:
an illumination system arranged at a first aperture in the tube-like element to illuminate with a beam of radiation a position in a trajectory of the droplet between a nozzle of the droplet generator and the irradiation region;
a detection system arranged at a second aperture in the tube-like element to receive radiation forward scattered by the droplet when the droplet traverses the position; and
an occlusion arranged in an optical path between the illumination system and the detection system to block the beam of radiation from directly reaching the detection system.
   21. The apparatus of clause 20 wherein the illumination system comprises a laser.
   22. The apparatus of clause 20 further comprising a removable pellicle positioned at the second aperture and wherein the occlusion is reflective and arranged on the removable pellicle.
   23. The apparatus of clause 20 further comprising a beam dump and wherein the occlusion is reflective and reflects at least a portion of the beam of radiation to the beam dump.
   24. The apparatus of clause 23 wherein the beam dump comprises a sensor arranged to measure a characteristic of stray light from the beam not forward scattered by the droplet and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.
   25. The apparatus of clause 20 wherein the detection system measures a stray light characteristic of stray light from the beam not forward scattered by the droplet and measures a forward scattered light characteristic of light forward scattered by the droplet and further comprising an electronics system arranged to receive information from the detection system, the electronics system being configured to generate an indication of the presence of the droplet at the position based on a homodyne method using the stray light characteristic and the forward scattered light characteristic.
   26. The apparatus of clause 20 wherein the illumination system, the detection system, and the occlusion are collinear along a common optical axis.
   27. The apparatus of clause 20 further comprising a pair of pellicles positioned at the first aperture.
   28. The apparatus of clause 20 wherein the illumination system, the detection system, and the occlusion are not collinear.
   29. The apparatus of clause 28 wherein an optical axis of the illumination system forms an angle of not less than 0° and not greater than 90° with an optical axis of the detection system.
   30. The apparatus of clause 20 wherein the detection system is a first detection system and further comprising a second detection system circumferentially displaced from the first detection system along a circumference of the tube-like element.
   31. The apparatus of clause 30 wherein the first detection system is adapted to detect radiation having a first characteristic and wherein the second detection system is adapted to detect radiation having a second characteristic.
   32. The apparatus of clause 31 wherein the first characteristic is a first wavelength and the second characteristic is a second wavelength.
   33. The apparatus of clause 32 wherein the first wavelength is the same as the second wavelength.
   34. The apparatus of clause 32 wherein the first wavelength is different from the second wavelength.
   35. The apparatus of clause 31 wherein the first characteristic is a first polarization and the second characteristic is a second polarization.
   36. The apparatus of clause 35 wherein the first polarization is the same as the second polarization.
   37. The apparatus of clause 35 wherein the first polarization is different from the second polarization.
   38. A method of detecting a droplet of target material for generating extreme ultraviolet radiation, the method comprising:
illuminating with a beam of radiation a position in a trajectory of the droplet between a droplet generator and an irradiation region;
detecting radiation from the beam forward scattered by the droplet when the droplet traverses the position; and
determining a characteristic of the droplet based at least in part on the radiation forward scattered by the droplet.
   39. The method of clause 38 wherein determining a characteristic of the droplet comprises determining the droplet's position.
   40. The method of clause 38 wherein determining a characteristic of the droplet comprises determining the droplet's size.
   41. The method of clause 38 wherein determining a characteristic of the droplet comprises determining the droplet's trajectory.
   42. The method of clause 38 further comprising detecting unscattered radiation from the beam and wherein determining a characteristic of the droplet comprises determining a characteristic of the droplet based at least in part on the radiation forward scattered by the droplet and the unscattered radiation from the beam using a homodyne method.
   43. The method of clause 42 wherein determining a characteristic of the droplet comprises determining the droplet's position.
   44. The method of clause 42 wherein determining a characteristic of the droplet comprises determining the droplet's size.
   45. The method of clause 42 wherein determining a characteristic of the droplet comprises determining the droplet's trajectory.
   46. The method of clause 42 wherein determining the droplet characteristic based at least in part on the radiation forward scattered by the droplet and the unscattered radiation from the beam using a homodyne method comprises using a detector.
   47. The method of clause 46 wherein the detector is part of a beam dump.
   48. A method of detecting a droplet of target material for generating extreme ultraviolet radiation, the method comprising:
illuminating with a beam of radiation a position between a droplet generator and an irradiation region; detecting a presence of a droplet at the position by detecting radiation from the beam forward scattered by the droplet when the droplet traverses the position.
   49. The method of clause 48 further comprising determining a characteristic of the droplet based at least in part on the radiation forward scattered by the droplet.
   50. The method of clause 48 wherein the position is a location along a trajectory of a droplet stream emanating from the droplet generator.
   51. Apparatus for detecting a droplet of target material, the target material being used for generating extreme ultraviolet radiation in an irradiation region, the apparatus comprising:
an illumination system arranged to illuminate with a beam of radiation a position in a trajectory of the droplet between a droplet generator and the irradiation region; and
a detection system arranged to receive and adapted to detect radiation side scattered by the droplet when the droplet traverses the position.
   52. The apparatus of clause 51 wherein the detection system generates a signal indicative of a presence of the droplet at the position based on detecting the radiation side scattered by the droplet when the droplet reaches the position.
   53. The apparatus of clause 51 wherein the illumination system comprises a laser.
   54. The apparatus of clause 51 further comprising a beam dump arranged to receive stray light from the detection system.
   55. The apparatus of clause 54 wherein the beam dump comprises a sensor arranged to measure a characteristic of stray light and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.
   56. The apparatus of clause 51 wherein an optical axis of the illumination system and an optical axis of the detection system are substantially orthogonal.
   57. The apparatus of clause 51 further comprising a stray light control system positioned parallel to an optical axis of at least one of the illumination system and the detection system to impede propagation of stray light.
   58. The apparatus of clause 51 wherein an optical axis of the illumination system forms an angle of not less than 0° and not greater than 90° with an optical axis of the detection system.
   59. The apparatus of clause 51 wherein an optical axis of the illumination system forms an angle of not less than 25° and not greater than 90° with an optical axis of the detection system.
   60. Apparatus for detecting a droplet of target material, the target material being used for generating extreme ultraviolet radiation in an irradiation region, the droplet being generated by a droplet generator, the apparatus comprising:
an illumination system arranged to illuminate with a beam of radiation a position in a trajectory of the droplet between a nozzle of the droplet generator and the irradiation region, the illumination system arranged at a first aperture in a tube-like element arranged circumferentially around the position; and
a detection system arranged at a second aperture in the tube-like element to receive radiation side scattered by the droplet when the droplet traverses the position.
   61. The apparatus of clause 60 wherein the droplet of target material is a part of a stream of droplets of target material, the tube-like element at least partially circumferentially surrounding a portion of the stream.
   62. The apparatus of clause 60 wherein the illumination system comprises a laser.
   63. The apparatus of clause 60 wherein the illumination system has a first optical axis and wherein the detection system has a second optical axis and wherein the first optical axis and the second optical axis are substantially orthogonal.
   64. The apparatus of clause 63 wherein the detection system comprises a detector spaced apart from the position in a first direction along the second optical axis and a beam dump spaced away from the position in a second direction along the second optical axis, the second direction being opposite to the first direction.
   65. The apparatus of clause 64 wherein the beam dump comprises a sensor arranged to measure a characteristic of stray light and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.
   66. The apparatus of clause 65 further comprising a first plurality of stray light containment structures positioned along the second optical axis between the detector and the position.
   67. The apparatus of clause 65 further comprising a second plurality of stray light containment structures positioned along the second optical axis between the beam dump and the position.
   68. The apparatus of clause 60 wherein an optical axis of the illumination system forms an angle of not greater than 90° with an optical axis of the detection system.
   69. The apparatus of clause 60 wherein the detection system is a first detection system and further comprising a second detection system circumferentially displaced from the first detection system along a circumference of the tube-like element.
   70. The apparatus of clause 69 wherein the first detection system is adapted to detect radiation having a first characteristic and wherein the second detection system is adapted to detect radiation having a second characteristic.
   71. The apparatus of clause 70 wherein the first characteristic is a first wavelength and the second characteristic is a second wavelength.
   72. The apparatus of clause 71 wherein the first wavelength is the same as the second wavelength.
   73. The apparatus of clause 71 wherein the first wavelength is different from the second wavelength.
   74. The apparatus of clause 70 wherein the first characteristic is a first polarization and the second characteristic is a second polarization.
   75. The apparatus of clause 74 wherein the first polarization is the same as the second polarization.
   76. The apparatus of clause 74 wherein the first polarization is different from the second polarization.
   77. A method of detecting a droplet of target material for generating extreme ultraviolet radiation, the method comprising:
illuminating with a beam of radiation a position in a trajectory of the droplet between a droplet generator and an irradiation region;
detecting radiation from the beam side scattered by the droplet when the droplet traverses the position; and
determining a characteristic of the droplet based at least in part on the radiation side scattered by the droplet.
   78. The method of clause 77 wherein determining a characteristic of the droplet comprises determining the droplet's position.
   79. The method of clause 77 wherein determining a characteristic of the droplet comprises determining the droplet's size.
   80. The method of clause 77 wherein determining a characteristic of the droplet comprises determining the droplet's trajectory.
   81. The method of clause 77 further comprising detecting unscattered radiation from the beam and wherein determining a characteristic of the droplet comprises determining a characteristic of the droplet based at least in part on the radiation side scattered by the droplet and the unscattered radiation from the beam using a homodyne method.
   82. The method of clause 81 wherein determining a characteristic of the droplet comprises determining the droplet's position.
   83. The method of clause 81 wherein determining a characteristic of the droplet comprises determining the droplet's size.
   84. The method of clause 81 wherein determining a characteristic of the droplet comprises determining the droplet's trajectory.
   85. The method of clause 81 wherein determining the droplet characteristic based at least in part on the radiation side scattered by the droplet and the unscattered radiation from the beam using a homodyne method comprises using a detector.
   86. A method of detecting a droplet of target material for generating extreme ultraviolet radiation, the method comprising:
illuminating with a beam of radiation a position between a droplet generator and an irradiation region; and
detecting a presence of a droplet at the position by detecting radiation from the beam side scattered by the droplet when the droplet traverses the position.
   87. The method of clause 86 further comprising determining a characteristic of the droplet based at least in part on the radiation side scattered by the droplet.
   88. The method of clause 87 wherein the characteristic is a position along a trajectory of a droplet stream emanating from the droplet generator.

The above described implementations and other implementations are within the scope of the following claims.

1-50. (canceled)

51. Apparatus for detecting a droplet of target material, the target material being used for generating extreme ultraviolet radiation in an irradiation region, the apparatus comprising:
an illumination system arranged to illuminate with a beam of radiation a position in a trajectory of the droplet between a droplet generator and the irradiation region; and
a detection system arranged to receive and adapted to detect radiation side scattered by the droplet when the droplet traverses the position.

52. (canceled)

53. The apparatus of claim 51 wherein the illumination system comprises a laser.

54. The apparatus of claim 51 further comprising a beam dump arranged to receive stray light from the detection system.

55. The apparatus of claim 54 wherein the beam dump comprises a sensor arranged to measure a characteristic of stray light and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.

56. (canceled)

57. The apparatus of claim 51 further comprising a stray light control system positioned parallel to an optical axis of at least one of the illumination system and the detection system to impede propagation of stray light.

58. (canceled)

59. The apparatus of claim 51 wherein an optical axis of the illumination system forms an angle of not less than 25° and not greater than 90° with an optical axis of the detection system.

60. Apparatus for detecting a droplet of target material, the target material being used for generating extreme ultraviolet radiation in an irradiation region, the droplet being generated by a droplet generator, the apparatus comprising:
an illumination system arranged to illuminate with a beam of radiation a position in a trajectory of the droplet between a nozzle of the droplet generator and the irradiation region, the illumination system arranged at a first aperture in a tube-like element arranged circumferentially around the position; and
a detection system arranged at a second aperture in the tube-like element to receive radiation side scattered by the droplet when the droplet traverses the position.

61. The apparatus of claim 60 wherein the droplet of target material is a part of a stream of droplets of target material, the tube-like element at least partially circumferentially surrounding a portion of the stream.

62. The apparatus of claim 60 wherein the illumination system comprises a laser.

63. The apparatus of claim 60 wherein the illumination system has a first optical axis and wherein the detection system has a second optical axis and wherein the first optical axis and the second optical axis are substantially orthogonal, wherein the detection system comprises a detector spaced apart from the position in a first direction along the second optical axis and a beam dump spaced away from the position in a second direction along the second optical axis, the second direction being opposite to the first direction.

64. (canceled)

65. The apparatus of claim 63 wherein the beam dump comprises a sensor arranged to measure a characteristic of stray light and adapted to generate a stray light signal indicative of the characteristic and further comprising an electronics system arranged to receive a detection signal from the detection system, the electronics system being configured to generate an indication of the presence of the droplet at the position based on a homodyne method using the detection signal and the stray light signal.

66. The apparatus of claim 65 further comprising a first plurality of stray light containment structures positioned along the second optical axis between the detector and the position.

67. (canceled)

68. (canceled)

69. The apparatus of claim 60 wherein the detection system is a first detection system and further comprising a second detection system circumferentially displaced from the first detection system along a circumference of the tube-like element.

70. The apparatus of claim 69 wherein the first detection system is adapted to detect radiation having a first characteristic and wherein the second detection system is adapted to detect radiation having a second characteristic wherein the first characteristic is a first wavelength and the second characteristic is a second wavelength.

71-73. (canceled)

74. The apparatus of claim 69 wherein the first detection system is adapted to detect radiation having a first characteristic and wherein the second detection system is adapted to detect radiation having a second characteristic wherein the first characteristic is a first polarization and the second characteristic is a second polarization.

75. (canceled)

76. (canceled)

77. A method of detecting a droplet of target material for generating extreme ultraviolet radiation, the method comprising:
illuminating with a beam of radiation a position in a trajectory of the droplet between a droplet generator and an irradiation region;
detecting radiation from the beam side scattered by the droplet when the droplet traverses the position; and
determining a characteristic of the droplet based at least in part on the radiation side scattered by the droplet.

78. (canceled)

79. The method of claim 77 wherein determining a characteristic of the droplet comprises determining the droplet's size.

80. The method of claim 77 wherein determining a characteristic of the droplet comprises determining the droplet's trajectory.

81. The method of claim 77 further comprising detecting unscattered radiation from the beam and wherein determining a characteristic of the droplet comprises determining a characteristic of the droplet based at least in part on the radiation side scattered by the droplet and the unscattered radiation from the beam using a homodyne method.

82. The method of claim 81 wherein determining a characteristic of the droplet comprises determining the droplet's position, the droplet's size or the droplet's trajectory.

83. (canceled)

84. (canceled)

85. The method of claim 81 wherein determining the droplet characteristic based at least in part on the radiation side scattered by the droplet and the unscattered radiation from the beam using a homodyne method comprises using a detector.

86. A method of detecting a droplet of target material for generating extreme ultraviolet radiation, the method comprising:
illuminating with a beam of radiation a position between a droplet generator and an irradiation region; and
detecting a presence of a droplet at the position by detecting radiation from the beam side scattered by the droplet when the droplet traverses the position.

87. (canceled)

88. (canceled)
